(19) United States
(12) Patent Application Publication
(10) Pub. No.: US 2017/0236855 A1
(43) Pub. Date: Aug. 17, 2017

(54) METHOD OF PRODUCING IMAGING PANEL, IMAGING PANEL, AND X-RAY IMAGING DEVICE

(71) Applicant: Sharp Kabushiki Kaisha, Sakai City, Osaka (JP)

(72) Inventors: Kazuhide TOMIYASU, Sakai City (JP); Tadayoshi MIYAMOTO, Sakai City (JP)

(21) Appl. No.: 15/501,500

(22) PCT Filed: Jul. 30, 2015
(86) PCT No.: PCT/JP2015/071576

§ 371 Date: Feb. 3, 2017

(30) Foreign Application Priority Data
Aug. 5, 2014 (JP) 2014-159792

(51) Int. Cl. H01L 27/146; H04N 5/32; G01T 1/20

(52) U.S. Cl. CPC H01L 27/14603; G01T 1/2018; H01L 27/14663; H01L 27/14616; H01L 27/14636; H01L 27/14689; H04N 5/32; H01L 29/78693

(57) ABSTRACT

An imaging panel (10) includes a photodiode (15), and a metal layer (43) provided below the photodiode and being in contact with a TFT (14) via a contact hole (CH1). A method of producing the imaging panel (10) includes forming a metal film (43p) covering to protect a first insulating film (42), subsequently forming semiconductor films to configure an n-type amorphous silicon layer (151), an intrinsic amorphous silicon layer (152), and a p-type amorphous silicon layer (153), and further forming the photodiode (15) by patterning the semiconductor films through dry etching.

### TECHNICAL FIELD

The present invention relates to a method of producing an imaging panel, the imaging panel, and an X-ray imaging device.

### BACKGROUND ART

A known X-ray imaging device includes an imaging panel provided with a plurality of pixel parts and configured to capture an X-ray image. Such an X-ray imaging device includes a photodiode configured to convert emitted X-rays to electric charges. In an indirect X-ray imaging device, a scintillator converts emitted X-rays to scintillation light and a photodiode converts the scintillation light thus converted to electric charges. The converted electric charges are read by a thin film transistor (hereinafter, also referred to as a “TFT”) in operation which is included in each pixel part. An X-ray image is obtained by reading the electric charges.

Patent Literature 1 discloses an imaging panel including a photodiode having an area rate increased for higher photosensor output performance. Patent Literature 1 describes a positional relation that a contact hole provided on a drain electrode has an opening edge involving an edge of the photodiode.

### CITATION LIST

### Patent Literature

Patent Literature 1: JP 2008-283113 A

### SUMMARY OF THE INVENTION

In an imaging panel of an X-ray imaging device, a TFT and a photodiode are disposed with an insulating film being interposed therebetween. Specifically, the TFT is disposed on a substrate, the insulating film covers the substrate and the TFT, and the photodiode is disposed on the insulating film. The TFT includes a drain electrode that is connected with the photodiode via a contact hole provided in the insulating film.

The photodiode is formed by patterning through dry etching. The TFT covered with the insulating film may be damaged by the dry etching to cause TFT threshold property variation.

It is an object of the present invention to provide an imaging panel having suppressed TFT threshold property variation by inhibiting damage to a TFT upon formation of a photodiode.

In order to achieve the object mentioned above, an imaging panel according to an embodiment of the present invention is configured to generate an image in accordance with X-rays having been transmitted through a target, and the imaging panel includes: a substrate; a plurality of thin film transistors provided on the substrate; a first insulating film covering the thin film transistors and having a plurality of contact holes each reaching a corresponding one of the thin film transistors; a plurality of metal layers each covering an inner side surface of a corresponding one of the contact holes and the first insulating film, and connected to a corresponding one of the thin film transistors; and a plurality of photodiodes each provided on and in contact with a corresponding one of the metal layers.

In order to achieve the object mentioned above, a method of producing an imaging panel according to an embodiment of the present invention relates to a method of producing an imaging panel configured to generate an image in accordance with X-rays having been transmitted through a target, and the method includes: forming a plurality of thin film transistors on a substrate; forming, on the substrate, a first insulating film covering the thin film transistors; forming, in the first insulating film, a plurality of contact holes each reaching a corresponding one of the thin film transistors; forming a metal film covering the first insulating film and an inner side surface of each of the contact holes; and forming a plurality of photodiodes by forming a semiconductor film and then patterning the semiconductor film into island shapes through dry etching.

The present invention provides an imaging panel having suppressed TFT threshold property variation by inhibiting damage to a TFT upon formation of a photodiode.

### BRIEF DESCRIPTION OF DRAWINGS

FIG. 1 is a pattern diagram of an X-ray imaging device according to an embodiment.

FIG. 2 is a pattern diagram depicting a schematic configuration of an imaging panel of FIG. 1.

FIG. 3 is a plan view of a pixel in the imaging panel of FIG. 2.

FIG. 4A is a sectional view taken along line A-A, of the pixel of FIG. 3.

FIG. 4B is a sectional view taken along line B-B, of the pixel of FIG. 3.

FIG. 5 includes a sectional view taken along line A-A and a sectional view taken along line B-B of the pixel of FIG. 3 in a process of producing a gate electrode of the pixel.

FIG. 6 includes a sectional view taken along line A-A and a sectional view taken along line B-B of the pixel of FIG. 3 in a process of producing a gate insulating film of the pixel.

FIG. 7 includes a sectional view taken along line A-A and a sectional view taken along line B-B of the pixel of FIG. 3 in a process of producing a semiconductor active layer of the pixel.

FIG. 8 includes a sectional view taken along line A-A and a sectional view taken along line B-B of the pixel of FIG. 3 in a process of producing a source electrode and a drain electrode of the pixel.

FIG. 9 includes a sectional view taken along line A-A and a sectional view taken along line B-B of the pixel of FIG. 3 in a process of producing a metal layer of the pixel.

FIG. 10 includes a sectional view taken along line A-A and a sectional view taken along line B-B of the pixel of FIG. 3 in a process of producing a photodiode of the pixel.

FIG. 11 includes a sectional view taken along line A-A and a sectional view taken along line B-B of the pixel of FIG. 3 in a process of producing an electrode of the pixel.

FIG. 12 includes a sectional view taken along line A-A and a sectional view taken along line B-B of the pixel of FIG. 3 in a process of patterning the metal layer of the pixel.

FIG. 13 is an enlarged sectional view of part of FIG. 12.

FIG. 14 includes a sectional view taken along line A-A and a sectional view taken along line B-B of the pixel of FIG. 3 in a process of producing a second interlayer insulating film of the pixel.

FIG. 15 includes a sectional view taken along line A-A and a sectional view taken along line B-B of the pixel of FIG. 3 in a process of producing a photosensitive resin layer of the pixel.

FIG. 16 includes a sectional view taken along line A-A and a sectional view taken along line B-B of the pixel of FIG. 3 in a process of producing a bias wire of the pixel.

FIG. 17 is a sectional view of a pixel in an imaging panel including a top gate TFT according to a modification example.

FIG. 18 is a sectional view of a pixel in an imaging panel including a TFT provided with an etch stopper layer according to another modification example.

### DESCRIPTION OF EMBODIMENTS

An imaging panel according to an embodiment of the present invention is configured to generate an image in accordance with X-rays having been transmitted through a target. The imaging panel includes: a substrate; a plurality of thin film transistors provided on the substrate; a first insulating film covering the thin film transistors and having a plurality of contact holes each reaching a corresponding one of the thin film transistors; a plurality of metal layers each covering an inner side surface of a corresponding one of the contact holes and the first insulating film, and connected to a corresponding one of the thin film transistors; and a plurality of photodiodes each provided on and in contact with a corresponding one of the metal layers (a first configuration).

The metal layers are each provided below the corresponding one of the photodiodes in the first configuration. The photodiodes are thus dry etched in the production of the imaging panel in the state where metal films to configure the metal layers are provided to cover the thin film transistors and the first insulating film. This configuration reduces damage by dry etching to the thin film transistors and thus suppresses threshold property variation of the thin film transistors.

According to a second configuration, preferably, each of the metal layers is entirely covered with the corresponding one of the photodiodes, and is smaller in area than the photodiode in the first configuration.

According to a third configuration, each of the metal layers is preferably a molybdenum film, a titanium film, or a film made of an alloy thereof in the first or second configuration.

An X-ray imaging device according to an embodiment of the present invention includes: the imaging panel having any one of the first to third configurations; a controller configured to control gate voltage of each of the thin film transistors and read a data signal according to electric charges converted by the photodiodes; and an X-ray source configured to emit X-rays (a fourth configuration).

A method of producing an imaging panel according to an embodiment of the present invention relates to a method of producing an imaging panel configured to generate an image in accordance with X-rays having been transmitted through a target, and the method includes: forming a plurality of thin film transistors on a substrate; forming, on the substrate, a first insulating film covering the thin film transistors; forming, in the first insulating film, a plurality of contact holes each reaching a corresponding one of the thin film transistors; forming a metal film covering the first insulating film and an inner side surface of each of the contact holes; and forming a plurality of photodiodes respectively corresponding to the contact holes by forming a semiconductor film and then patterning the semiconductor film into island shapes through dry etching (a first production method).

The first production method includes forming the metal film covering the first insulating film, and then forming the photodiodes by dry etching. The photodiodes are thus dry etched in the state where the metal film covers to protect a surface of a first conductive film. In other words, the metal film serves as a protective film of the first insulating film and the thin film transistors provided therebelow upon dry etching. This configuration reduces damage by dry etching to the thin film transistors and thus suppresses threshold property variation of the thin film transistors.

A second production method is achieved by adding, to the first production method, a process of forming a metal layer, after forming the plurality of photodiodes, by removing a region not covered with the photodiodes in the metal film by wet etching.

An embodiment of the present invention will be described in detail below with reference to the drawings. Identical or corresponding portions in the drawings will be denoted by identical reference signs and will not be described repeatedly.

The expression “connected” in the present description indicates connection between two members in contact with each other as well as electrical connection between two members via a third conductive member disposed between the two members.

### (Configuration)

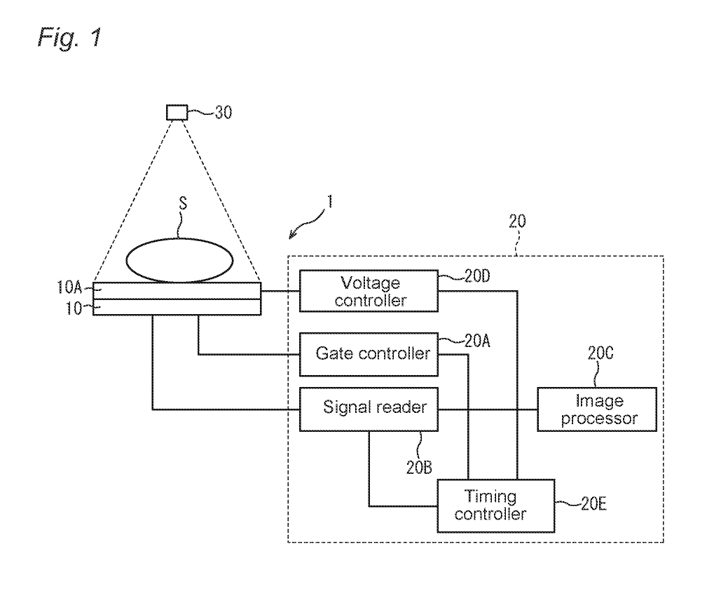

FIG. 1 is a pattern diagram of an X-ray imaging device according to the present embodiment. The X-ray imaging device 1 includes an imaging panel 10 and a controller 20. X-rays are applied from an X-ray source 30 to a target S, and the X-rays having been transmitted through the target S are converted to fluorescence (hereinafter, referred to as scintillation light) by a scintillator 10A disposed on the imaging panel 10. The X-ray imaging device 1 captures the scintillation light with use of the imaging panel 10 and the controller 20 to obtain an X-ray image.

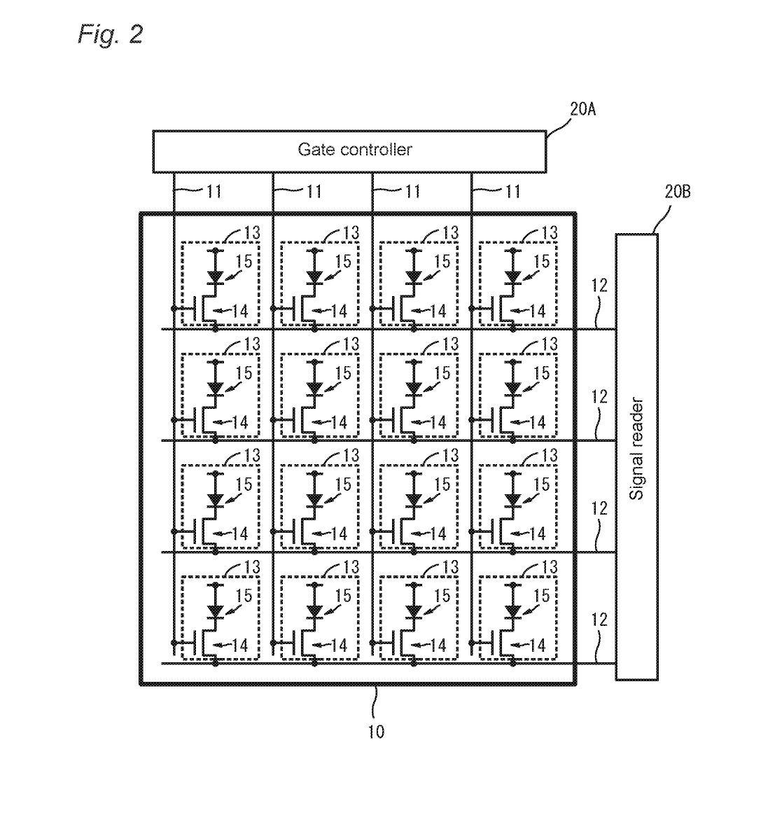

FIG. 2 is a pattern diagram depicting a schematic configuration of the imaging panel 10. As depicted in FIG. 2, the imaging panel 10 includes a plurality of gate lines 11 and a plurality of data lines 12 crossing the gate lines 11. The imaging panel 10 further includes a plurality of pixels 13 defined by the gate lines 11 and the data lines 12. FIG. 2 exemplifies the imaging panel 10 including 16 pixels 13 (in four lines and four columns), although the imaging panel 10 is not limited in the number of pixels.

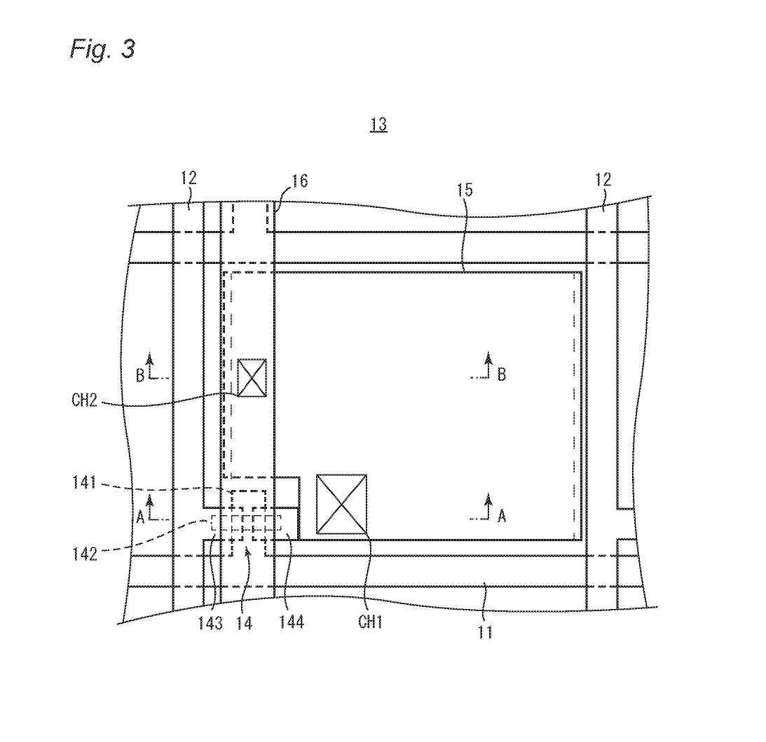

The pixels 13 each include a TFT 14 connected to a corresponding one of the gate lines 11 and a corresponding one of the data lines 12, and a photodiode 15 connected to the TFT 14. Although not depicted in FIG. 2, each of the pixels 13 is further provided with a bias wire 16 (see FIG. 3) configured to supply the photodiode 15 with bias voltage and disposed substantially in parallel with the data line 12.

In each of the pixels 13, the photodiode 15 converts the scintillation light converted from the X-rays having been transmitted through the target S to electric charges according to the amount of the scintillation light.

The gate lines 11 in the imaging panel 10 are sequentially switched to a selected state by a gate controller 20A, and the TFT 14 connected to the gate line 11 in the selected state is switched into an ON state. When the TFT 14 comes into the ON state, a data signal according to the electric charges converted by the photodiode 15 is transmitted to the data line 12.

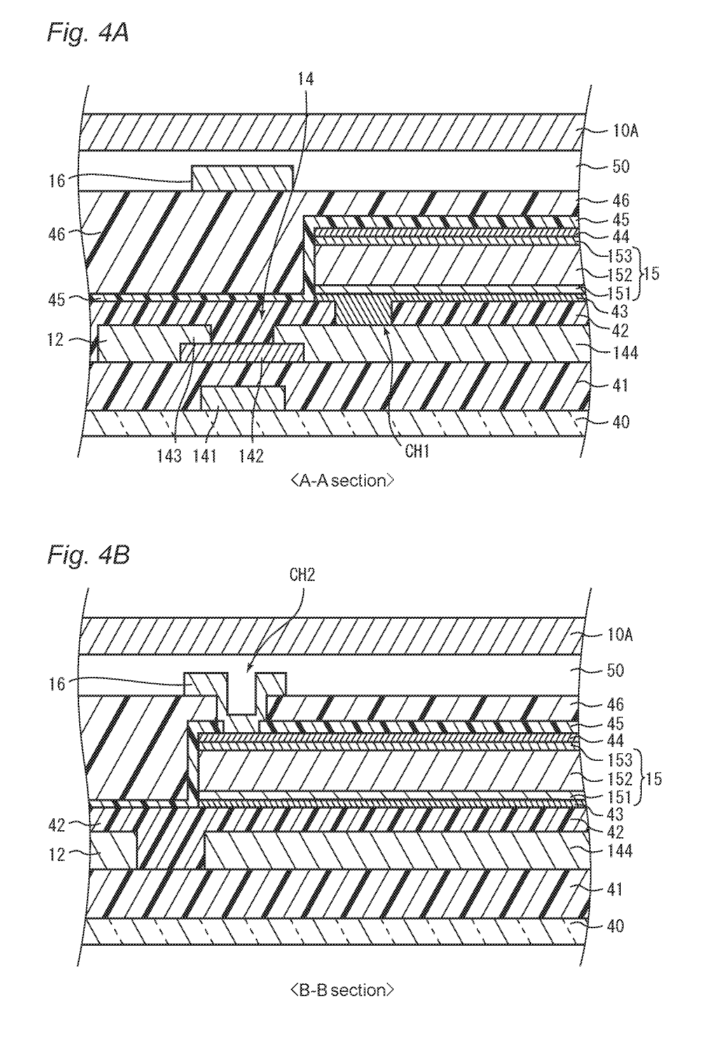

Described next is a specific configuration of the pixel 13. FIG. 3 is a plan view of the pixel 13 in the imaging panel 10 depicted in FIG. 2. FIG. 4A is a sectional view taken along line A-A, of the pixel 13 of FIG. 3, and FIG. 4B is a sectional view taken along line B-B, of the pixel 13 of FIG. 3.

As depicted in FIGS. 4A and 4B, the pixel 13 is provided on a substrate 40. The substrate 13 is an insulating substrate, examples of which include a glass substrate, a silicon substrate, a heat-resistant plastic substrate, and a resin substrate. Specifically, the plastic substrate or the resin substrate can be made of polyethylene terephthalate (PET), polyethylene naphthalate (PEN), polyether sulfone (PES), acryl, polyimide, or the like.

The TFT 14 includes a gate electrode 141, a semiconductor active layer 142 disposed above the gate electrode 141 with a gate insulating film 41 being interposed therebetween, and a source electrode 143 and a drain electrode 144 connected to the semiconductor active layer 142.

The gate electrode 141 is provided in contact with one of surfaces in the thickness direction (hereinafter, referred to as a main surface) of the substrate 40. The gate electrode 141 is made of a metal such as aluminum (Al), tungsten (W), molybdenum (Mo), tantalum (Ta), chromium (Cr), titanium (Ti), or copper (Cu), an alloy thereof, or a metal nitride thereof. The gate electrode 141 can alternatively include a plurality of stacked metal films. The gate electrode 141 according to the present embodiment has a stacked layer structure including a metal film made of aluminum and a metal film made of titanium stacked in the mentioned order.

As depicted in FIGS. 4A and 4B, the gate insulating film 41 is provided on the substrate 40 and covers the gate electrode 141. The gate insulating film 41 is made of a silicon oxide (SiOₓ), a silicon nitride (SiNₓ), a silicon oxidized nitride (SiOₓN_{y}) (x>y), a silicon nitrided oxide (SiNₓO_{y}) (x>y), or the like.

As depicted in FIG. 4A, the semiconductor active layer 142 is provided in contact with the gate insulating film 41. The semiconductor active layer 142 is made of an oxide semiconductor. Examples of the oxide semiconductor include an amorphous oxide semiconductor containing InGaO₃(ZnO)₅, a magnesium zinc oxide (MgₓZn₁₋ₓO), a cadmium zinc oxide (CdₓZn₁₋ₓO), cadmium oxide (CdO), or indium (In), gallium (Ga), and zinc (Zn) at predetermined ratios. The semiconductor active layer 142 can be made of ZnO containing, as an additive, one or a plurality of impurity elements in Groups 1, 13, 14, 15, and 17, in a noncrystalline (amorphous) state or in a polycrystalline state. The ZnO can be in a microcrystalline state mixedly including the amorphous state and the polycrystalline state, or contains no additive of any impurity element.

As depicted in FIG. 4A, the source electrode 143 and the drain electrode 144 are provided in contact with the semiconductor active layer 142 and the gate insulating film 41. As depicted in FIG. 3, the source electrode 143 is connected to the data line 12. As depicted in FIG. 4A, the drain electrode 144 is connected to a metal layer 43 to be described later via a first contact hole CH1. The source electrode 143, the data line 12, and the drain electrode 144 are provided in an identical layer.

The source electrode 143, the data line 12, and the drain electrode 144 are made of a metal such as aluminum (Al), tungsten (W), molybdenum (Mo), tantalum (Ta), chromium (Cr), titanium (Ti), or copper (Cu), an alloy thereof, or a metal nitride thereof. The source electrode 143, the data line 12, and the drain electrode 144 can alternatively be made of a light-transmissive material such as indium tin oxide (ITO), indium zinc oxide (IZO), indium tin oxide containing silicon oxide (ITSO), indium oxide (In₂O₃), tin oxide (SnO₂), zinc oxide (ZnO), or titanium nitride, or appropriate combinations thereof.

The source electrode 143, the data line 12, and the drain electrode 144 can alternatively include a plurality of stacked metal films. The source electrode 143, the data line 12, and the drain electrode 144 according to the present embodiment have a stacked layer structure including a metal film made of titanium, a metal film made of aluminum, and a metal film made of titanium stacked in the mentioned order.

As depicted in FIGS. 4A and 4B, there is provided a first interlayer insulating film 42 covering the semiconductor active layer 142, the source electrode 143, the data line 12, and the drain electrode 144. The first interlayer insulating film 42 can have a single layer structure including silicon oxide (SiO₂) or silicon nitride (SiN), or a stacked layer structure including silicon nitride (SiN) and silicon oxide (SiO₂) stacked in the mentioned order.

As depicted in FIG. 4A, the first interlayer insulating film 42 is provided with the first contact hole CH1 reaching the drain electrode 144.

As depicted in FIGS. 4A and 4B, the first interlayer insulating film 42 is provided thereon with the metal layer 43. As depicted in FIG. 4A, the metal layer 43 also covers the inner wall surface of the first contact hole CH1. The metal layer 43 covers the inner wall surface of the first contact hole CH1 and is thus in contact with the drain electrode 144. The metal layer 43 is provided in a region substantially identical to a region provided with the photodiode 15 to be described later. That is, a plurality of metal layers 43 is provided correspondingly to the pixels 13.

The metal layer 43 is provided as a molybdenum (Mo) film, a titanium (Ti) film, a film made of an alloy thereof, or the like. The metal layer 43 can have a single layer structure or a stacked layer structure. The metal layer 43 according to the present embodiment is provided as a molybdenum (Mo) film.

As depicted in FIGS. 4A and 4B, the photodiode 15 is provided on the metal layer 43. The photodiode 15 at least includes a first semiconductor layer of a first conductivity type and a second semiconductor layer of a second conductivity type opposite to the first conductivity type. The photodiode 15 according to the present embodiment includes an n-type amorphous silicon layer 151, an intrinsic amorphous silicon layer 152, and a p-type amorphous silicon layer 153.

The n-type amorphous silicon layer 151 is made of amorphous silicon doped with an n-type impurity (e.g. phosphorus). The n-type amorphous silicon layer 151 is provided in contact with the metal layer 43. The n-type amorphous silicon layer 151 is in contact with the metal layer 43 and the metal layer 43 is in contact with the drain electrode 144, so that the n-type amorphous silicon layer 151 is connected with the drain electrode 144. The n-type amorphous silicon layer 151 is typically 20 to 100 nm thick.

The intrinsic amorphous silicon layer 152 is made of intrinsic amorphous silicon. The intrinsic amorphous silicon layer 152 is provided in contact with the n-type amorphous silicon layer 151. The intrinsic amorphous silicon layer is typically 200 to 2000 nm thick.

The p-type amorphous silicon layer 153 is made of amorphous silicon doped with a p-type impurity (e.g. boron). The p-type amorphous silicon layer 153 is provided in contact with the intrinsic amorphous silicon layer 152. The p-type amorphous silicon layer 153 is typically 10 to 50 nm thick.

The drain electrode 144 functions as a drain electrode of the TFT 14 and functions also as a lower electrode of the photodiode 15. The drain electrode 144 further functions as a reflective film reflecting scintillation light having been transmitted through the photodiode 15 to be directed to the photodiode 15.

As depicted in FIGS. 4A and 4B, the photodiode 15 is provided thereon with an upper electrode 44 functioning as an upper electrode of the photodiode 15. The upper electrode 44 is made of indium zinc oxide (IZO) or the like. The drain electrode 144 functioning as a lower electrode, the metal layer 43 connected to potential of the drain electrode 144, the photodiode 15, and the upper electrode 44 configure a photoelectric transducer.

As depicted in FIGS. 4A and 4B, there is provided a second interlayer insulating film 45 in contact with the first interlayer insulating film 42. The second interlayer insulating film 45 covers side surfaces of the metal layer 43, the photodiode 15, and the upper electrode 44, and a peripheral edge of the upper electrode 44.

The second interlayer insulating film 45 is made of silicon oxide (SiO), silicon nitride (SiN), silicon oxynitride (SiON), or the like. The second interlayer insulating film 45 can have a single layer structure or a stacked layer structure. The second interlayer insulating film 45 is typically 50 to 200 nm thick.

As depicted in FIGS. 4A and 4B, the second interlayer insulating film 45 is provided thereon with a photosensitive resin layer 46. The photosensitive resin layer 46 is made of an organic resin material or an inorganic resin material.

As depicted in FIG. 4B, the second interlayer insulating film 45 and the photosensitive resin layer 46 are provided with a second contact hole CH2 reaching the upper electrode 44.

As depicted in FIGS. 3, 4A, and 4B, the bias wire 16 is provided on the photosensitive resin layer 46 and substantially in parallel with the data line 12. Specifically, as depicted in FIGS. 3 and 4A, the bias wire 16 is provided on the photosensitive resin layer 46 to overlap the TFT 14. The bias wire 16 is connected to a voltage controller 20D (see FIG. 1). As depicted in FIG. 4B, the bias wire 16 is connected to the upper electrode 44 via the second contact hole CH2 and applies bias voltage received from the voltage controller 20D to the upper electrode 44. The bias wire 16 has a stacked layer structure including indium zinc oxide (IZO) and molybdenum (Mo), for example.

As depicted in FIGS. 4A and 4B, the imaging panel 10, specifically, the photosensitive resin layer 46, is provided thereon with a protective layer 50 covering the bias wire 16, and the scintillator 10A is provided on the protective layer 50.

Described with reference to FIG. 1 again is a configuration of the controller 20. The controller 20 includes the gate controller 20A, a signal reader 20B, an image processor 20C, the voltage controller 20D, and a timing controller 20E.

As depicted in FIG. 2, the gate controller 20A is connected with the plurality of gate lines 11. The gate controller 20A applies, via each of the gate lines 11, predetermined gate voltage to the TFT 14 included in the pixel 13 connected to the gate line 11.

As depicted in FIG. 2, the signal reader 20B is connected with the plurality of data lines 12. The signal reader 20B reads, via each of the data lines 12, a data signal according to electric charges converted by the photodiode 15 included in the pixel 13. The signal reader 20B generates an image signal according to the data signal and transmits the image signal to the image processor 20C.

The image processor 20C generates an X-ray image in accordance with the image signal transmitted from the signal reader 20B.

The voltage controller 20D is connected to each of the bias wires 16. The voltage controller 20D applies predetermined bias voltage to the bias wire 16. The bias voltage is thus applied to the photodiode 15 via the upper electrode 44 connected to the bias wire 16.

The timing controller 20E controls operation timing of the gate controller 20A, the signal reader 20B, and the voltage controller 20D.

The gate controller 20A selects one of the gate lines 11 in accordance with a control signal transmitted from the timing controller 20E. The gate controller 20A applies, via the selected gate line 11, predetermined gate voltage to the TFT 14 included in the pixel 13 connected to the gate line 11.

The signal reader 20B selects one of the data lines 12 in accordance with the control signal transmitted from the timing controller 20E. The signal reader 20B reads, via the selected data line 12, a data signal according to electric charges converted by the photodiode 15 in the pixel 13. The pixel 13 relevant to the read data signal is connected to the data line 12 selected by the signal reader 20B and is connected to the gate line 11 selected by the gate controller 20A.

The timing controller 20E transmits a control signal to the voltage controller 20D in an exemplary case where the X-ray source 30 emits X-rays. The voltage controller 20D applies predetermined bias voltage to the upper electrode 44 in accordance with the control signal.

### (Operation of X-ray Imaging Device 10)

The X-ray source 30 initially emits X-rays. The timing controller 20E transmits a control signal to the voltage controller 20D in this case. For example, a control device configured to control operation of the X-ray source 30 transmits, to the timing controller 20E, a signal indicating that the X-ray source 30 is emitting X-rays. Upon receiving the signal, the timing controller 20E transmits a control signal to the voltage controller 20D. The voltage controller 20D applies predetermined voltage (bias voltage) to the bias wire 16 in accordance with the control signal transmitted from the timing controller 20E.

The X-rays emitted from the X-ray source 30 are transmitted through the target S and enter the scintillator 10A. The X-rays having entered the scintillator 10A are converted to fluorescence (scintillation light) that enters the imaging panel 10.

When the scintillation light enters the photodiode 15 provided in each of the pixels 13 of the imaging panel 10, the photodiode 15 converts the scintillation light to electric charges according to the amount of the scintillation light.

When the TFT 14 is made in the ON state by gate voltage (positive voltage) transmitted from the gate controller 20A through the gate line 11, the signal reader 20B reads, via the data line 12, a data signal according to the electric charges converted by the photodiode 15. The image processor 20C generates an X-ray image according to the read data signal.

### (Method of Producing Imaging Panel 10)

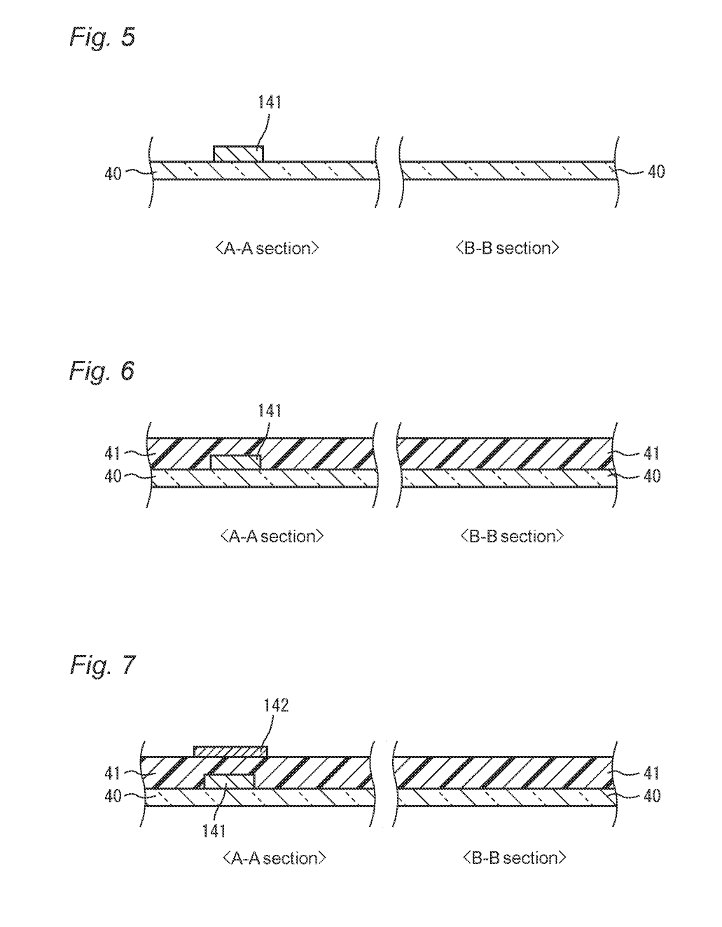

Described next is a method of producing the imaging panel 10. FIGS. 5 to 12 and 14 to 16 include sectional views taken along line A-A and sectional views taken along line B-B of the pixel 13 in respective processes of producing the imaging panel 10.

A metal film is initially formed on the substrate 40 by stacking aluminum and titanium through sputtering or the like. As depicted in FIG. 5, the metal film is patterned in accordance with the photolithography method to form the gate electrode 141 and the gate line 11 (not depicted in FIG. 5; see FIG. 3). The metal film is typically 300 nm thick.

As depicted in FIG. 6, the gate insulating film 41 made of a silicon oxide (SiOₓ), a silicon nitride (SiNₓ), or the like and covering the gate electrode 141 and the gate line 11 is subsequently formed on the substrate 40 in accordance with the plasma CVD method, through sputtering, or the like. The gate insulating film 41 is typically 20 to 150 nm thick.

As depicted in FIG. 7, an oxide semiconductor film is subsequently formed on the gate insulating film 41 through sputtering or the like and is patterned in accordance with the photolithography method to form the semiconductor active layer 142. The semiconductor active layer 142 thus formed is optionally heat treated in an atmosphere containing oxygen (e.g. ambient air) at a high temperature (e.g. 350° C. or more). This reduces an oxygen defect of the semiconductor active layer 142. The semiconductor active layer 142 is typically 30 to 100 nm thick.

A metal film including titanium, aluminum, and titanium stacked in the mentioned order is subsequently formed through sputtering or the like on the gate insulating film 41 and the semiconductor active layer 142. As depicted in FIG. 8, the metal film is then patterned in accordance with the photolithography method to form the source electrode 143, the data line 12, and the drain electrode 144. The source electrode 143, the data line 12, and the drain electrode 144 are typically 50 to 500 nm thick. Etching can be performed by dry etching or wet etching. Dry etching is preferred if the substrate 40 has a large area. The TFT 14 of a bottom gate type is thus formed.

As depicted in FIG. 8, the first interlayer insulating film 42 made of silicon oxide (SiO₂) or silicon nitride (SiN) is subsequently formed in accordance with the plasma CVD method or the like on the source electrode 143, the data line 12, and the drain electrode 144. The substrate 40 is then entirely heat treated at about 350° C., and the first interlayer insulating film 42 is patterned in accordance with the photolithography method to form the first contact hole CH1.

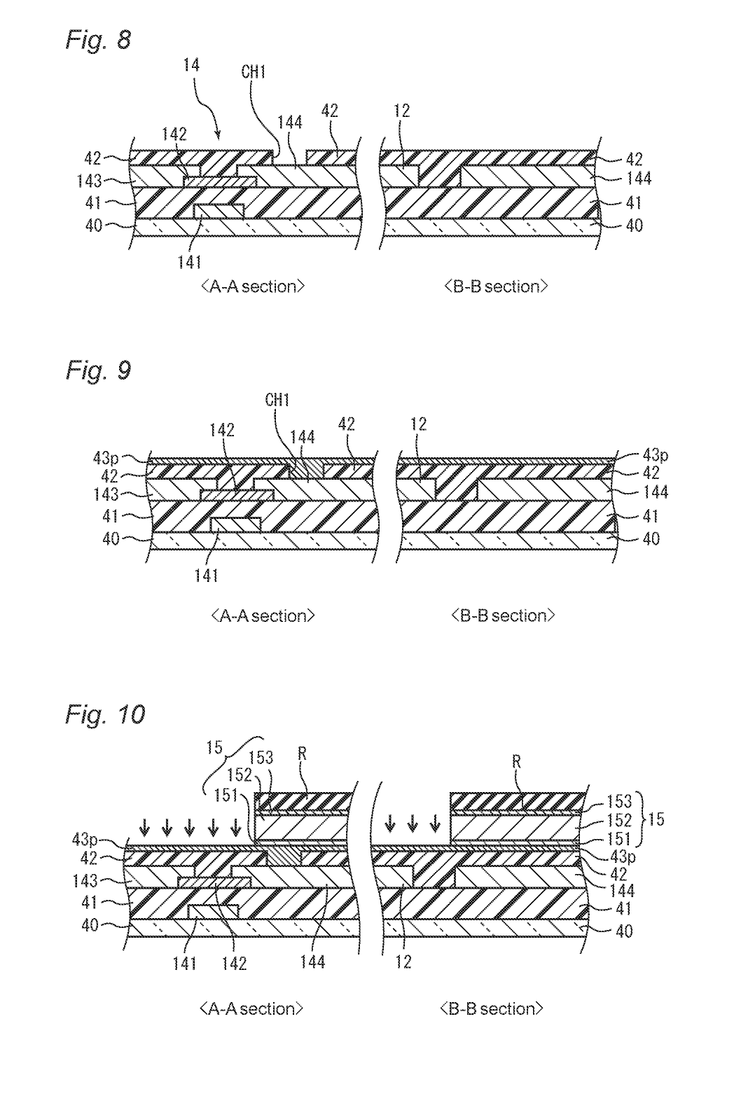

As depicted in FIG. 9, a metal film 43p made of molybdenum (Mo) is then formed on the first interlayer insulating film 42 through sputtering or the like. The metal film 43p is to configure the metal layer 43 later. The metal film 43p is provided to cover also the inner wall surface of the first contact hole CH1. The metal film 43p is in contact with the drain electrode 144 at the first contact hole CH1.

Subsequently formed on the metal film 43p through sputtering or the like are an n-type amorphous silicon layer 151p, an intrinsic amorphous silicon layer 152p, and a p-type amorphous silicon layer 153p in the mentioned order. The drain electrode 144 and the n-type amorphous silicon layer 151p are connected with each other via the metal film 43p in this state.

The n-type amorphous silicon layer 151, the intrinsic amorphous silicon layer 152, and the p-type amorphous silicon layer 153 are then patterned in accordance with the photolithography method and are dry etched to form the photodiode 15. Specifically, as depicted in FIG. 10, a resist R is formed on a region to configure the photodiode 15 in the n-type amorphous silicon layer 151, the intrinsic amorphous silicon layer 152, and the p-type amorphous silicon layer 153. The region not covered with the resist R is irradiated with plasma to remove unnecessary portions of the n-type amorphous silicon layer 151p, the intrinsic amorphous silicon layer 152p, and the p-type amorphous silicon layer 153p, to form the n-type amorphous silicon layer 151, the intrinsic amorphous silicon layer 152, and the p-type amorphous silicon layer 153. The region irradiated with plasma (see arrows indicated in FIG. 10) is provided with the metal film 43p.

Dry etching is performed in the state where the first interlayer insulating film 42 is covered with the metal film 43p so that etching gas will not come into direct contact with the first interlayer insulating film 42. Even in a case where the etching gas contains fluorine or chlorine, fluorine or chlorine contained in the first interlayer insulating film 42 will not increase in concentration. For example, in a case where interfacial analysis of the first interlayer insulating film 42 is executed in accordance with the shared information management system (SIMS), the first interlayer insulating film 42 has a fluorine concentration of 10 ppm or less. In another case where interfacial analysis of the first interlayer insulating film 42 is executed in accordance with the X-ray photoelectron spectroscopy (XPS), the first interlayer insulating film 42 has a fluorine concentration of 1 atm % or less.

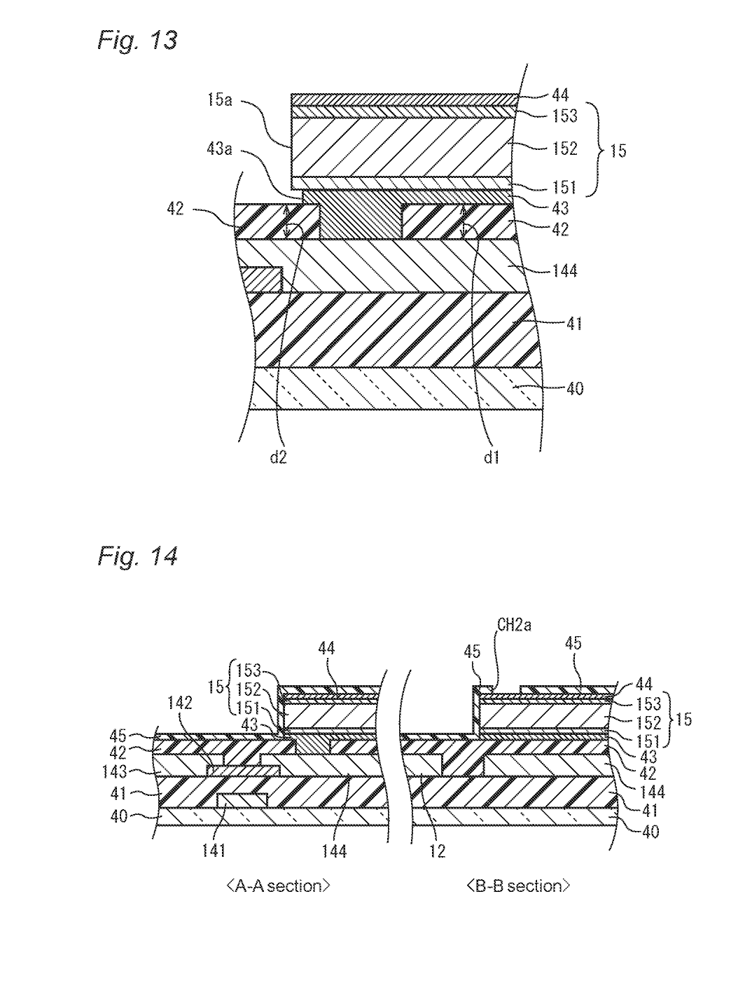

Dry etching is performed in the state where the first interlayer insulating film 42 is covered with the metal film 43p so that the first interlayer insulating film 42 will not be etched during the dry etching. The region covered with the metal layer 43 in the first interlayer insulating film 42 thus has a thickness (see a thickness d1 indicated in FIG. 13 to be referred to later) equal to a thickness of the region not covered with the metal layer 43 (see a thickness d2 indicated in FIG. 13).

As depicted in FIG. 11, an indium zinc oxide (IZO) film is subsequently formed on the first interlayer insulating film 42 and the photodiode 15 through sputtering or the like and is patterned in accordance with the photolithography method to form the upper electrode 44.

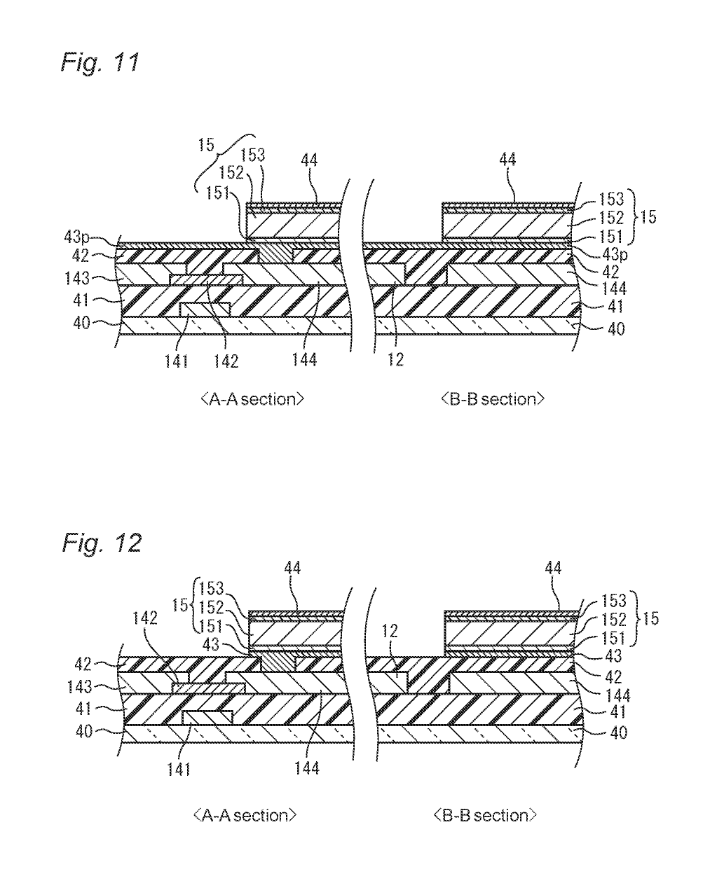

As depicted in FIG. 12, the metal film 43p is then patterned by wet etching to form the metal layer 43. Etching is performed with use of an etching solution, examples of which include a nitric acid-containing etching solution, a sulfuric acid-containing etching solution, a phosphoric acid-containing etching solution, and an acetic acid-containing etching solution. The region not provided with the photodiode 15 in the first interlayer insulating film 42 is thus not covered with the metal film 43p.

The metal layer 43 according to the present embodiment is made of molybdenum. In a case where the metal layer 43 is a titanium film, an etching solution containing nitric acid, hydrogen peroxide, or the like is applicable in the process of wet etching the metal film 43p.

FIG. 13 is an enlarged sectional view of a periphery of the metal layer 43 having been wet etched. In the wet etching process, the etching solution extends to reach below the photodiode 15 to cause a so-called undercut phenomenon. Specifically, as depicted in FIG. 13, the metal layer 43 has a side surface 43a positioned inside, in an in-plane direction of the photodiode 15, a side surface 15a of the photodiode 15. In other words, the metal layer 43 is slightly smaller in area than the photodiode 15.

As depicted in FIG. 14, a silicon oxide (SiO₂) film or a silicon nitride (SiN) film is then formed on the first interlayer insulating film 42 and the upper electrode 44 in accordance with the plasma CVD method or the like, to form the second interlayer insulating film 45. The second interlayer insulating film 45 is patterned in accordance with the photolithography method, to form, on the upper electrode 44, an opening CH2a to configure the second contact hole CH2.

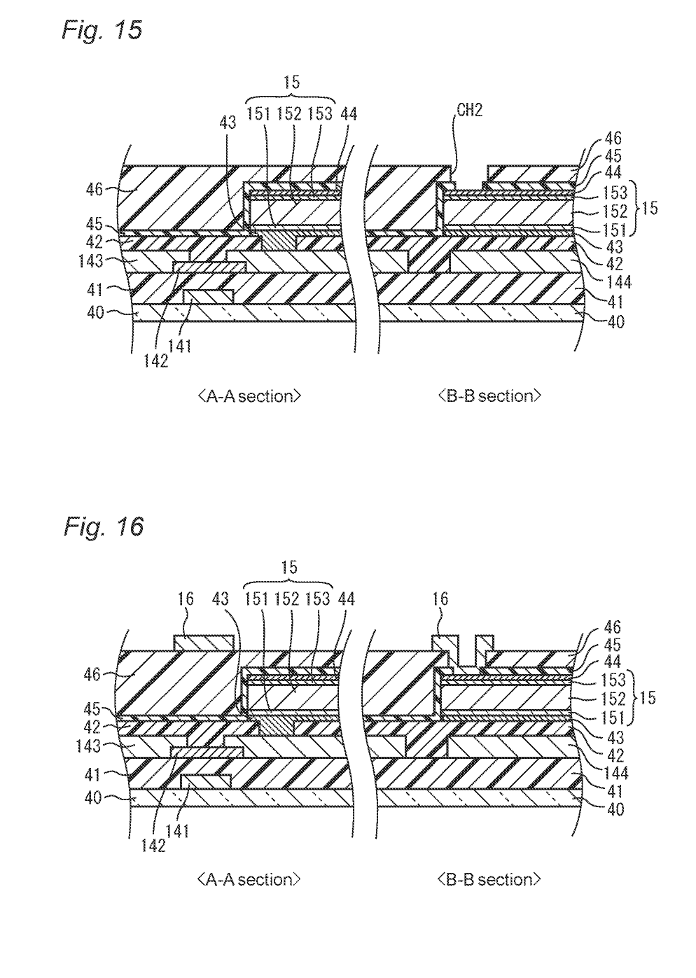

As depicted in FIG. 15, a photosensitive resin film is subsequently formed on the second interlayer insulating film 45, is dried, and is patterned in accordance with the photolithography method, to form the photosensitive resin layer 46. The photosensitive resin layer 46 is provided with an opening corresponding to the opening CH2a of the second interlayer insulating film 45 to form the second contact hole CH2.

As depicted in FIG. 16, a metal film is subsequently formed on the photosensitive resin layer 46 by stacking indium zinc oxide (IZO) and molybdenum (Mo) through sputtering or the like, and is patterned in accordance with the photolithography method, to form the bias wire 16.

The imaging panel according to the present embodiment includes the metal layer 43 provided below the photodiode 15. As described above, the photodiode 15 is dry etched in the state where the region irradiated with plasma (see the arrows indicated in FIG. 10) is provided with the metal film 43p that is provided to configure the metal layer 43. The metal film 43p thus absorbs any influence of plasma applied in the process of dry etching the photodiode 15. In other words, the TFT 14 is inhibited from being damaged by dry etching to the photodiode 15. This will suppress TFT threshold property variation.

The process of patterning the metal film 43p to obtain the metal layer 43 is executed by wet etching and will not involve plasma application. Accordingly, removal of the metal film 43p will not affect the threshold property of the TFT 14.

### MODIFICATION EXAMPLES

Modification examples of the present invention will be described below.

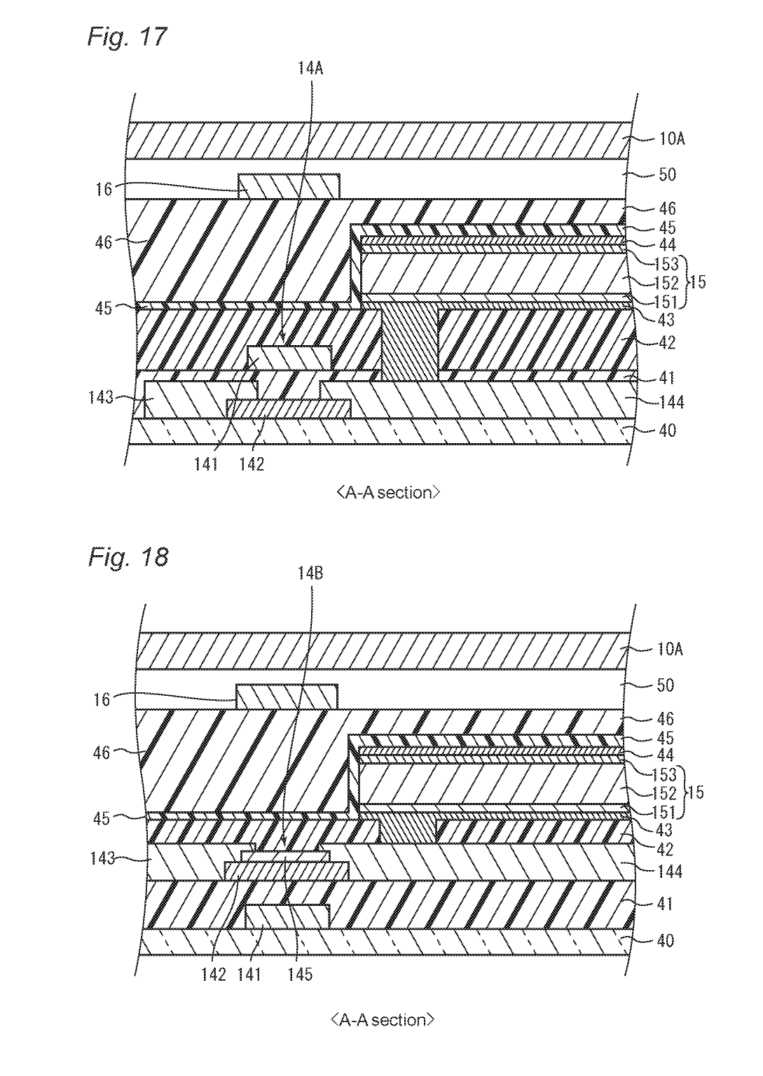

The embodiment described above exemplifies the imaging panel 10 including the TFTs 14 of the bottom gate type. Alternatively, each of the TFTs can be replaced with a TFT 14A of a top gate type as depicted in FIG. 17 or a TFT 14B of a bottom gate type as depicted in FIG. 18.

A method of producing an imaging panel including the TFTs 14A of the top gate type of FIG. 17 will be described by referring to differences from the method according to the above embodiment. Initially formed on the substrate 40 is the semiconductor active layer 142 made of an oxide semiconductor. The source electrode 143, the data line 12, and the drain electrode 144 are then formed by stacking titanium, aluminum, and titanium in the mentioned order on the substrate 40 and the semiconductor active layer 142.

The gate insulating film 41 made of a silicon oxide (SiOₓ), a silicon nitride (SiNₓ), or the like is subsequently formed on the semiconductor active layer 142, the source electrode 143, the data line 12, and the drain electrode 144. The gate electrode 141 and the gate line 11 are then formed by stacking aluminum and titanium on the gate insulating film 41.

After the gate electrode 141 is formed, the first interlayer insulating film 42 is formed on the gate insulating film 41 to cover the gate electrode 141, and the first contact hole CH1 penetrating to reach the drain electrode 144 is formed. As in the above embodiment, the photodiode 15 is to be formed on the first interlayer insulating film 42 and the drain electrode 144.

In order to produce an imaging panel including the TFTs 14B each provided with an etch stopper layer 145 as depicted in FIG. 18, after the semiconductor active layer 142 is formed in the above embodiment, a silicon oxide (SiO₂) film is formed on the semiconductor active layer 142 in accordance with the plasma CVD method or the like. The silicon oxide (SiO₂) film is then patterned in accordance with the photolithography method to form the etch stopper layer 145. After the etch stopper layer 145 is formed, the source electrode 143, the data line 12, and the drain electrode 144 are to be formed by stacking titanium, aluminum, and titanium in the mentioned order on the semiconductor active layer 142 and the etch stopper layer 145.

The above embodiment provides the indirect X-ray imaging device 1 including the scintillator 10A. The present invention is not particularly limited thereto. The present invention is applicable also to a direct X-ray imaging device including no scintillator. Specifically, the direct X-ray imaging device includes an imaging panel provided with a photoelectric transducer configured to convert X-rays received from the X-ray source 30 to electricity.

The embodiment of the present invention described above is merely exemplified to achieve the present invention. The present invention should not be limited to the above embodiment, and can be achieved with appropriate modifications to the above embodiment without departing from the spirit of the present invention.

### INDUSTRIAL APPLICABILITY

The present invention is applicable to a method of producing an imaging panel, the imaging panel, and an X-ray imaging device.

1. An imaging panel configured to generate an image in accordance with X-rays having been transmitted through a target, the imaging panel comprising:
a substrate;
a plurality of thin film transistors provided on the substrate;
a first insulating film covering the thin film transistors and having a plurality of contact holes each reaching a corresponding one of the thin film transistors;
a plurality of metal layers each covering an inner side surface of a corresponding one of the contact holes and the first insulating film, and connected to a corresponding one of the thin film transistors; and
a plurality of photodiodes each provided on and in contact with a corresponding one of the metal layers.

2. The imaging panel according to claim 1, wherein
each of the metal layers is entirely covered with the corresponding one of the photodiodes, and is smaller in area than the photodiode.

3. The imaging panel according to claim 1, wherein
each of the metal layers is a molybdenum film, a titanium film, or a film made of an alloy thereof.

4. An X-ray imaging device comprising:
the imaging panel according to claim 1;
a controller configured to control gate voltage of each of the thin film transistors and read a data signal according to electric charges converted by the photodiodes; and
an X-ray source configured to emit X-rays.

5. A method of producing an imaging panel configured to generate an image in accordance with X-rays having been transmitted through a target, the method comprising:
forming a plurality of thin film transistors on a substrate;
forming, on the substrate, a first insulating film covering the thin film transistors;
forming, in the first insulating film, a plurality of contact holes each reaching a corresponding one of the thin film transistors;
forming a metal film covering the first insulating film and an inner side surface of each of the contact holes; and
forming a plurality of photodiodes respectively corresponding to the contact holes by forming a semiconductor film and then patterning the semiconductor film into island shapes through dry etching.

6. The method of producing the imaging panel according to claim 5, the method further comprising:
forming a metal layer, after forming the plurality of photodiodes, by removing a region not covered with the photodiodes in the metal film by wet etching.
